(19) United States
(12) Patent Application Publication
(10) Pub. No.: US 2020/0098501 A1
(43) Pub. Date: Mar. 26, 2020

(54) VARIABLE INDUCTIVE ELECTRICAL COMPONENT FOR CROSSTALK MODIFICATION

(71) Applicant: QUALCOMM Incorporated, San Diego, CA (US)

(72) Inventor: Veit MEISTER, Unterhaching (DE)

(21) Appl. No.: 16/142,712

(22) Filed: Sep. 26, 2018

(51) Int. Cl. H01F 21/12; H03H 11/04; H03H 1/00

(52) U.S. Cl. CPC H01F 21/12; H03H 2001/0092; H03H 1/0007; H03H 11/04

(57) ABSTRACT

Certain aspects of the present disclosure provide a circuit, chip, and method for modifying crosstalk between an inductive component and an electrical component. One example circuit generally includes an electrical component, a variable inductive component comprising switches and one or more conductor paths, a controller configured to control the switches of the variable inductive component to modify crosstalk between the variable inductive component and the electrical component.

### BACKGROUND

### Field of the Disclosure

Aspects of the present disclosure relate to circuits having inductive electrical components, and more particularly, to techniques for modifying magnetic field crosstalk between inductive electrical components and other electrical components arranged adjacent to the inductive electrical components.

### Description of Related Art

The continued emphasis in semiconductor technology is to create improved performance semiconductor devices at competitive prices. This emphasis over the years has resulted in extreme miniaturization of semiconductor devices, made possible by continued advances of semiconductor processes and materials in combination with new and sophisticated device designs. Most of the semiconductor devices that are at this time being created are aimed at processing digital data. There are however also numerous semiconductor designs that are aimed at incorporating analog functions into devices that simultaneously process digital and analog data, or devices that can be used for the processing of only analog data.

For example, a wireless communication device may include a radio frequency front-end (RFFE) for transmitting and/or receiving radio frequency signals. The RFFE may include an inductive electrical component that performs analog functions such as an analog base band filter. The RFFE may also include digital components such as a digital-to-analog converter (DAC) and/or an analog-to-digital converter (ADC).

### BRIEF SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include improved circuits for modifying crosstalk between inductive electrical components and other electrical components.

Certain aspects provide a circuit for reducing crosstalk between components. The circuit generally includes a variable inductive component comprising one or more switches and a plurality of conductor paths, and a controller configured to control the one or more switches of the variable inductive component to adjust an inductance of the variable inductive component to a selected inductance value, the controller further configured to control the one or more switches to alter a direction of current through at least one of the plurality of conductor paths.

Certain aspects provide a circuit for modifying crosstalk between an electrical component and a variable inductive component. The circuit generally includes an electrical component, a variable inductive component comprising switches and one or more conductor paths, a controller configured to control the switches of the variable inductive component to modify crosstalk between the variable inductive component and the electrical component.

Certain aspects provide a chip for modifying crosstalk between an electrical component and a variable inductive component. The chip generally includes an electrical component arranged on a substrate material, a variable inductive component comprising switches and one or more conductor paths arranged on the substrate material, and a controller arranged on the substrate material and configured control the switches of the variable inductive component to to modify crosstalk between the variable inductive component and the electrical component.

Certain aspects provide a method of modifying crosstalk between an electrical component and a variable inductive component. The method generally includes applying a signal to a variable inductive component comprising switches and one or more conductor paths, and controlling the switches of the variable inductive component to modify crosstalk between the variable inductive component and the electrical component.

Certain aspects provide a circuit for reducing crosstalk between an electrical component and a variable inductive component. The circuit general includes a variable inductive component comprising one or more switches and one or more conductor paths, and a controller configured to control the one or more switches of the variable inductive component to adjust an inductance of the variable inductive component to a selected inductance value, the controller further configured to control the one or more switches to alter a direction of current through at least one of the one or more conductive paths while maintaining the inductance at the selected inductance value.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 is a block diagram conceptually illustrating an example telecommunications system, in accordance with certain aspects of the present disclosure.

FIG. 2 is a block diagram conceptually illustrating a design of an example base station (BS) and user equipment (UE), in accordance with certain aspects of the present disclosure.

FIG. 3 is a block diagram showing an example transceiver front end, in accordance with certain aspects of the present disclosure.

FIG. 4 illustrates a block diagram view of an example circuit configured to modify crosstalk between an inductive component and an adjacent electrical component, in accordance with certain aspects of the present disclosure.

FIG. 5A illustrates a schematic view of an example variable inductor, in accordance with certain aspects of the present disclosure.

FIG. 5B illustrates a schematic view of a portion of the variable inductor of FIG. 5A, in accordance with certain aspects of the present disclosure

FIGS. 5C and 5D illustrate schematic views of example conductor spacing of the variable inductor of FIG. 5A, in accordance with certain aspects of the present disclosure.

FIG. 6A illustrates a schematic view of an example variable inductor that has a different spacing from the electrical component for each coil, in accordance with certain aspects of the present disclosure.

FIG. 6B illustrates a schematic view of an example variable inductor, in accordance with certain aspects of the present disclosure.

FIG. 6C illustrates a schematic view of an example variable inductor, in accordance with certain aspects of the present disclosure.

FIG. 7 illustrates a schematic view of an example switch network, in accordance with certain aspects of the present disclosure.

FIGS. 8A-D illustrate schematic views of example variable inductors, in accordance with certain aspects of the present disclosure.

FIGS. 9A and 9B illustrate schematic views of example variable transformers, in accordance with certain aspects of the present disclosure.

FIGS. 10A and 10B illustrate schematic views of example variable transformers, in accordance with certain aspects of the present disclosure.

FIGS. 11A-G illustrate schematic views of various switch configurations of a variable inductor, in accordance with certain aspects of the present disclosure.

FIG. 12 is a flow diagram illustrating example operations for modifying crosstalk, in accordance with certain aspects of the present disclosure

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Aspects of the present disclosure provide apparatus, methods, and processing systems for modifying magnetic field crosstalk between an inductive electrical component (also referred to herein as an “inductive component”) and another electrical component arranged adjacent to each other.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The techniques described herein may be used for various wireless communication technologies, such as LTE, CDMA, TDMA, FDMA, OFDMA, SC-FDMA and other networks. The terms “network” and “system” are often used interchangeably. A CDMA network may implement a radio technology such as Universal Terrestrial Radio Access (UTRA), cdma2000, etc. UTRA includes Wideband CDMA (WCDMA) and other variants of CDMA. cdma2000 covers IS-2000, IS-95 and IS-856 standards. A TDMA network may implement a radio technology such as Global System for Mobile Communications (GSM). An OFDMA network may implement a radio technology such as NR (e.g. 5G RA), Evolved UTRA (E-UTRA), Ultra Mobile Broadband (UMB), IEEE 802.11 (Wi-Fi), IEEE 802.16 (WiMAX), IEEE 802.20, Flash-OFDMA, etc. UTRA and E-UTRA are part of Universal Mobile Telecommunication System (UMTS).

New Radio (NR) is an emerging wireless communications technology under development in conjunction with the 5G Technology Forum (5GTF). 3GPP Long Term Evolution (LTE) and LTE-Advanced (LTE-A) are releases of UMTS that use E-UTRA. UTRA, E-UTRA, UMTS, LTE, LTE-A and GSM are described in documents from an organization named “3rd Generation Partnership Project” (3GPP). cdma2000 and UMB are described in documents from an organization named “3rd Generation Partnership Project 2” (3GPP2). The techniques described herein may be used for the wireless networks and radio technologies mentioned above as well as other wireless networks and radio technologies. For clarity, while aspects may be described herein using terminology commonly associated with 3G and/or 4G wireless technologies, aspects of the present disclosure can be applied in other generation-based communication systems, such as 5G and later, including NR technologies.

New radio (NR) access (e.g., 5G technology) may support various wireless communication services, such as enhanced mobile broadband (eMBB) targeting wide bandwidth (e.g., 80 MHz or beyond), millimeter wave (mmW) targeting high carrier frequency (e.g., 25 GHz or beyond), massive machine type communications MTC (mMTC) targeting non-backward compatible MTC techniques, and/or mission critical targeting ultra-reliable low-latency communications (URLLC). These services may include latency and reliability requirements. These services may also have different transmission time intervals (TTI) to meet respective quality of service (QoS) requirements. In addition, these services may co-exist in the same subframe.

### Example Wireless Communications System

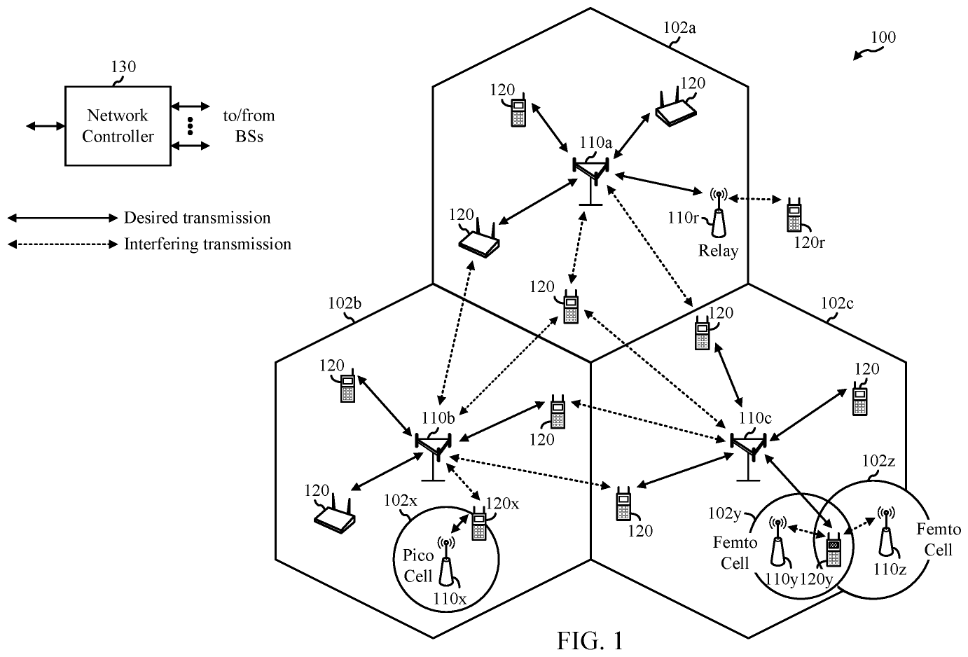

FIG. 1 illustrates an example wireless communication network 100 in which aspects of the present disclosure may be performed. For example, the wireless communication network 100 may be a New Radio (NR) or 5G network. Wireless devices in the communication network 100 may be equipped with circuits described herein to modify crosstalk between an inductive electrical component and another electrical component arranged adjacent to each other.

As illustrated in FIG. 1, the wireless network 100 may include a number of base stations (BSs) 110 and other network entities. A BS may be a station that communicates with user equipments (UEs). Each BS 110 may provide communication coverage for a particular geographic area. In 3GPP, the term “cell” can refer to a coverage area of a Node B (NB) and/or a Node B subsystem serving this coverage area, depending on the context in which the term is used. In NR systems, the term “cell” and next generation NodeB (gNB), new radio base station (NR BS), 5G NB, access point (AP), or transmission reception point (TRP) may be interchangeable. In some examples, a cell may not necessarily be stationary, and the geographic area of the cell may move according to the location of a mobile BS. In some examples, the base stations may be interconnected to one another and/or to one or more other base stations or network nodes (not shown) in wireless communication network 100 through various types of backhaul interfaces, such as a direct physical connection, a wireless connection, a virtual network, or the like using any suitable transport network.

In general, any number of wireless networks may be deployed in a given geographic area. Each wireless network may support a particular radio access technology (RAT) and may operate on one or more frequencies. A RAT may also be referred to as a radio technology, an air interface, etc. A frequency may also be referred to as a carrier, a subcarrier, a frequency channel, a tone, a subband, etc. Each frequency may support a single RAT in a given geographic area in order to avoid interference between wireless networks of different RATs. In some cases, NR or 5G RAT networks may be deployed.

A base station (BS) may provide communication coverage for a macro cell, a pico cell, a femto cell, and/or other types of cells. A macro cell may cover a relatively large geographic area (e.g., several kilometers in radius) and may allow unrestricted access by UEs with service subscription. A pico cell may cover a relatively small geographic area and may allow unrestricted access by UEs with service subscription. A femto cell may cover a relatively small geographic area (e.g., a home) and may allow restricted access by UEs having an association with the femto cell (e.g., UEs in a Closed Subscriber Group (CSG), UEs for users in the home, etc.). A BS for a macro cell may be referred to as a macro BS. A BS for a pico cell may be referred to as a pico BS. A BS for a femto cell may be referred to as a femto BS or a home BS. In the example shown in FIG. 1, the BSs 110a, 110b and 110c may be macro BSs for the macro cells 102a, 102b and 102c, respectively. The BS 110x may be a pico BS for a pico cell 102x. The BSs 110y and 110z may be femto BSs for the femto cells 102y and 102z, respectively. A BS may support one or multiple (e.g., three) cells.

Wireless communication network 100 may also include relay stations. A relay station is a station that receives a transmission of data and/or other information from an upstream station (e.g., a BS or a UE) and sends a transmission of the data and/or other information to a downstream station (e.g., a UE or a BS). A relay station may also be a UE that relays transmissions for other UEs. In the example shown in FIG. 1, a relay station 110r may communicate with the BS 110a and a UE 120r in order to facilitate communication between the BS 110a and the UE 120r. A relay station may also be referred to as a relay BS, a relay, etc.

Wireless network 100 may be a heterogeneous network that includes BSs of different types, e.g., macro BS, pico BS, femto BS, relays, etc. These different types of BSs may have different transmit power levels, different coverage areas, and different impact on interference in the wireless network 100. For example, macro BS may have a high transmit power level (e.g., 20 Watts) whereas pico BS, femto BS, and relays may have a lower transmit power level (e.g., 1 Watt).

Wireless communication network 100 may support synchronous or asynchronous operation. For synchronous operation, the BSs may have similar frame timing, and transmissions from different BSs may be approximately aligned in time. For asynchronous operation, the BSs may have different frame timing, and transmissions from different BSs may not be aligned in time. The techniques described herein may be used for both synchronous and asynchronous operation.

A network controller 130 may couple to a set of BSs and provide coordination and control for these BSs. The network controller 130 may communicate with the BSs 110 via a backhaul. The BSs 110 may also communicate with one another (e.g., directly or indirectly) via wireless or wireline backhaul.

The UEs 120 (e.g., 120x, 120y, etc.) may be dispersed throughout the wireless network 100, and each UE may be stationary or mobile. A UE may also be referred to as a mobile station, a terminal, an access terminal, a subscriber unit, a station, a Customer Premises Equipment (CPE), a cellular phone, a smart phone, a personal digital assistant (PDA), a wireless modem, a wireless communication device, a handheld device, a laptop computer, a cordless phone, a wireless local loop (WLL) station, a tablet computer, a camera, a gaming device, a netbook, a smartbook, an ultrabook, an appliance, a medical device or medical equipment, a biometric sensor/device, a wearable device such as a smart watch, smart clothing, smart glasses, a smart wrist band, smart jewelry (e.g., a smart ring, a smart bracelet, etc.), an entertainment device (e.g., a music device, a video device, a satellite radio, etc.), a vehicular component or sensor, a smart meter/sensor, industrial manufacturing equipment, a global positioning system device, or any other suitable device that is configured to communicate via a wireless or wired medium. Some UEs may be considered machine-type communication (MTC) devices or evolved MTC (eMTC) devices. MTC and eMTC UEs include, for example, robots, drones, remote devices, sensors, meters, monitors, location tags, etc., that may communicate with a BS, another device (e.g., remote device), or some other entity. A wireless node may provide, for example, connectivity for or to a network (e.g., a wide area network such as Internet or a cellular network) via a wired or wireless communication link. Some UEs may be considered Internet-of-Things (loT) devices, which may be narrowband loT (NB-IoT) devices.

Certain wireless networks (e.g., LTE) utilize orthogonal frequency division multiplexing (OFDM) on the downlink and single-carrier frequency division multiplexing (SC-FDM) on the uplink. OFDM and SC-FDM partition the system bandwidth into multiple (K) orthogonal subcarriers, which are also commonly referred to as tones, bins, etc. Each subcarrier may be modulated with data. In general, modulation symbols are sent in the frequency domain with OFDM and in the time domain with SC-FDM. The spacing between adjacent subcarriers may be fixed, and the total number of subcarriers (K) may be dependent on the system bandwidth. For example, the spacing of the subcarriers may be 15 kHz and the minimum resource allocation (called a “resource block” (RB)) may be 12 subcarriers (or 180 kHz). Consequently, the nominal Fast Fourier Transfer (FFT) size may be equal to 128, 256, 512, 1024 or 2048 for system bandwidth of 1.25, 2.5, 5, 10, or 20 megahertz (MHz), respectively. The system bandwidth may also be partitioned into subbands. For example, a subband may cover 1.8 MHz (i.e., 6 resource blocks), and there may be 1, 2, 4, 8, or 16 subbands for system bandwidth of 1.25, 2.5, 5, 10 or 20 MHz, respectively.

While aspects of the examples described herein may be associated with LTE technologies, aspects of the present disclosure may be applicable with other wireless communications systems, such as NR. NR may utilize OFDM with a CP on the uplink and downlink and include support for half-duplex operation using TDD. Beamforming may be supported and beam direction may be dynamically configured. MIMO transmissions with precoding may also be supported. MIMO configurations in the DL may support up to 8 transmit antennas with multi-layer DL transmissions up to 8 streams and up to 2 streams per UE. Multi-layer transmissions with up to 2 streams per UE may be supported. Aggregation of multiple cells may be supported with up to 8 serving cells.

In some examples, access to the air interface may be scheduled, wherein a. A scheduling entity (e.g., a base station) allocates resources for communication among some or all devices and equipment within its service area or cell. The scheduling entity may be responsible for scheduling, assigning, reconfiguring, and releasing resources for one or more subordinate entities. That is, for scheduled communication, subordinate entities utilize resources allocated by the scheduling entity. Base stations are not the only entities that may function as a scheduling entity. In some examples, a UE may function as a scheduling entity and may schedule resources for one or more subordinate entities (e.g., one or more other UEs), and the other UEs may utilize the resources scheduled by the UE for wireless communication. In some examples, a UE may function as a scheduling entity in a peer-to-peer (P2P) network, and/or in a mesh network. In a mesh network example, UEs may communicate directly with one another in addition to communicating with a scheduling entity.

In FIG. 1, a solid line with double arrows indicates desired transmissions between a UE and a serving BS, which is a BS designated to serve the UE on the downlink and/or uplink. A finely dashed line with double arrows indicates interfering transmissions between a UE and a BS.

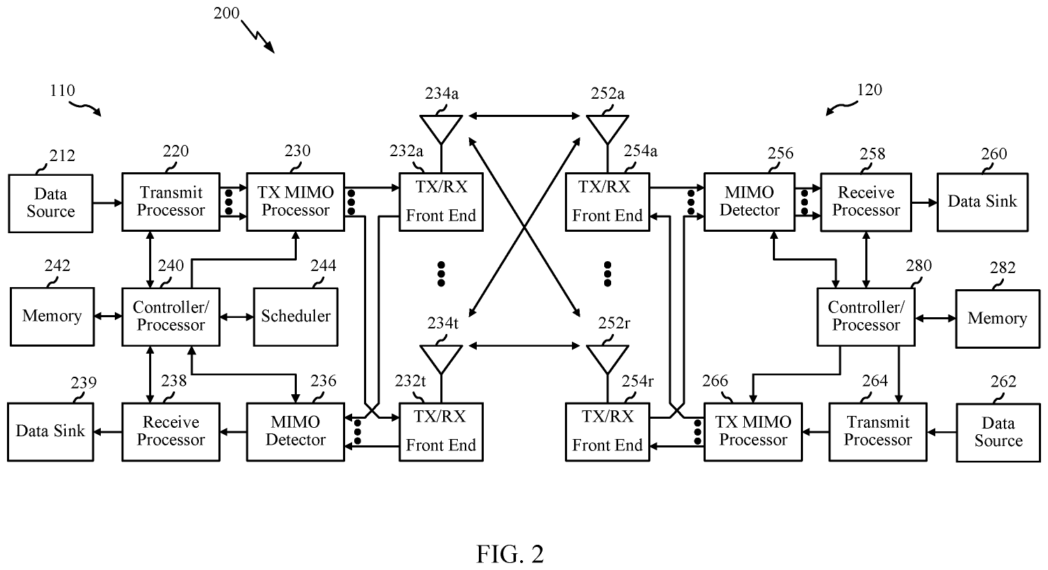

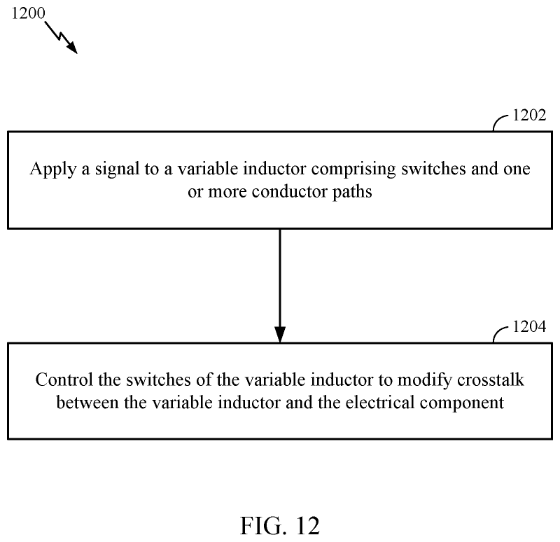

FIG. 2 illustrates example components of BS 110 and UE 120 (as depicted in FIG. 1), which may be used to implement aspects of the present disclosure. For example, antennas 252, processors 266, 258, 264, and/or controller/processor 280 of the UE 120 and/or antennas 234, processors 220, 240, 238, and/or controller/processor 240 of the BS 110 may be used to perform the various techniques and methods described herein such as illustrated in FIG. 12.

At the BS 110, a transmit processor 220 may receive data from a data source 212 and control information from a controller/processor 240. The control information may be for the physical broadcast channel (PBCH), physical control format indicator channel (PCFICH), physical hybrid ARQ indicator channel (PHICH), physical downlink control channel (PDCCH), group common PDCCH (GC PDCCH), etc. The data may be for the physical downlink shared channel (PDSCH), etc. The processor 220 may process (e.g., encode and symbol map) the data and control information to obtain data symbols and control symbols, respectively. The processor 220 may also generate reference symbols, e.g., for the primary synchronization signal (PSS), secondary synchronization signal (SSS), and cell-specific reference signal (CRS). A transmit (TX) multiple-input multiple-output (MIMO) processor 230 may perform spatial processing (e.g., precoding) on the data symbols, the control symbols, and/or the reference symbols, if applicable, and may provide output symbol streams to the transmit (TX) front end circuit 232a through 232t. Each TX front end circuit 232 may process a respective output symbol stream (e.g., for OFDM, etc.) to obtain an output sample stream. Each TX front end circuit may further process (e.g., convert to analog, amplify, filter, and upconvert) the output sample stream to obtain a downlink signal. Downlink signals from the TX front end circuits 232a through 232t may be transmitted via the antennas 234a through 234t, respectively.

At the UE 120, the antennas 252a through 252r may receive the downlink signals from the BS 110 and may provide received signals to the receive (RX) front end circuits 254a through 254r, respectively. Each RX front end circuit 254 may condition (e.g., filter, amplify, downconvert, and digitize) a respective received signal to obtain input samples. Each RX front end circuit may further process the input samples (e.g., for OFDM, etc.) to obtain received symbols. A MIMO detector 256 may obtain received symbols from all the RX front end circuits 254a through 254r, perform MIMO detection on the received symbols if applicable, and provide detected symbols. A receive processor 258 may process (e.g., demodulate, deinterleave, and decode) the detected symbols, provide decoded data for the UE 120 to a data sink 260, and provide decoded control information to a controller/processor 280.

On the uplink, at UE 120, a transmit processor 264 may receive and process data (e.g., for the physical uplink shared channel (PUSCH)) from a data source 262 and control information (e.g., for the physical uplink control channel (PUCCH) from the controller/processor 280. The transmit processor 264 may also generate reference symbols for a reference signal (e.g., for the sounding reference signal (SRS)). The symbols from the transmit processor 264 may be precoded by a TX MIMO processor 266 if applicable, further processed by the TX/RX front end circuits 254a through 254r (e.g., for SC-FDM, etc.), and transmitted to the BS 110. At the BS 110, the uplink signals from the UE 120 may be received by the antennas 234, processed by the TX/RX front end circuits 232, detected by a MIMO detector 236 if applicable, and further processed by a receive processor 238 to obtain decoded data and control information sent by the UE 120. The receive processor 238 may provide the decoded data to a data sink 239 and the decoded control information to the controller/processor 240.

The controllers/processors 240 and 280 may direct the operation at the BS 110 and the UE 120, respectively. The controller/processor 240 and/or other processors and modules at the BS 110 may perform or direct the execution of processes for the techniques described herein. The memories 242 and 282 may store data and program codes for BS 110 and UE 120, respectively. A scheduler 244 may schedule UEs for data transmission on the downlink and/or uplink.

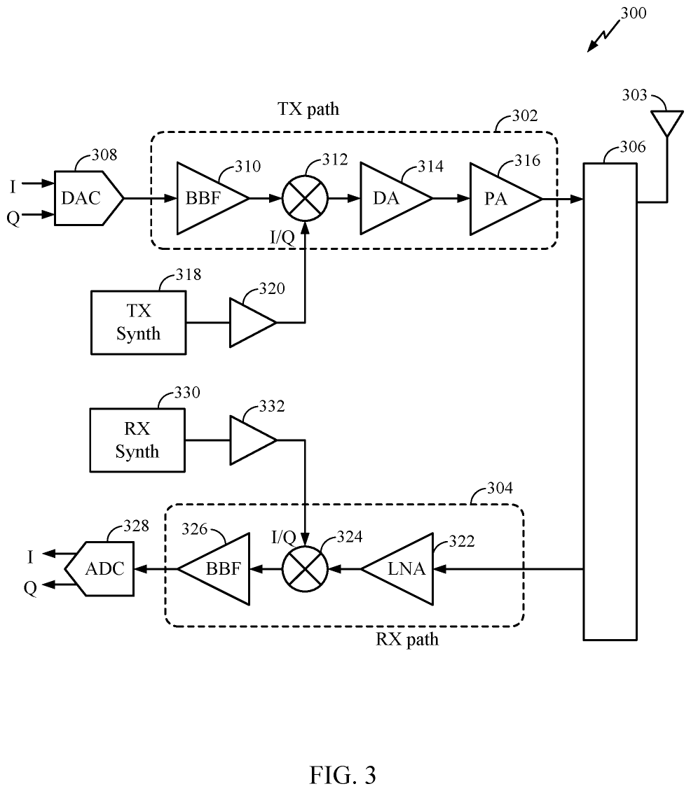

FIG. 3 is a block diagram of an example transceiver front end 300, such as TX/RX front end circuits 232, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be included in the RFIC or external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies between the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 may include a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO may be produced by a TX frequency synthesizer 318, which may be buffered or amplified by amplifier 320 before being mixed with the baseband signals in the mixer 312. Similarly, the receive LO may be produced by an RX frequency synthesizer 330, which may be buffered or amplified by amplifier 332 before being mixed with the RF signals in the mixer 324.

### Example Variable Inductive Component for Crosstalk Modification

As indicated above, electrical devices may simultaneously process digital and analog data. Such analog devices, such as inductive electrical components (e.g., inductors and transformers), have the problem of generating stray electromagnetic (EM) fields that may interfere with adjacent electrical components. For instance, an energized inductor may produce magnetic field emissions (also referred to herein as magnetic field crosstalk or crosstalk), which may induce an electric current in an adjacent electrical component (e.g., a bus bar such as a conductive trace embedded in an integrated circuit). This induced electric current may disturb electrical signals applied to the electrical component. Thus, the magnetic field crosstalk emitted from inductive electrical components can lead to an undesirable induced current that causes the electrical component to perform poorly or not function as designed.

A transceiver front end (e.g., transceiver front end 300) may be an example of a circuit that has inductive electrical components proximate to other electrical components susceptible to being disturbed by magnetic crosstalk from inductive components. In certain aspects, the circuits described herein include at least one variable inductive component designed to modify the crosstalk between the variable inductive component and the adjacent electrical component. This may enable the circuit to modify (e.g., increase or reduce) the crosstalk disturbance produced from a variable inductive component. In certain aspects, a variable inductive component includes one or more of a variable inductor, an inductive transformer (e.g., a switchable transformer (e.g. Balun)), or a variometer. In certain aspects, a circuit as described herein may reduce crosstalk, which may limit a working range of the circuit. In certain aspects, a circuit as described herein may increase crosstalk such as if the phase difference between two circuit parts will lead to a reduction of a disturbing signal or to improve suppression.

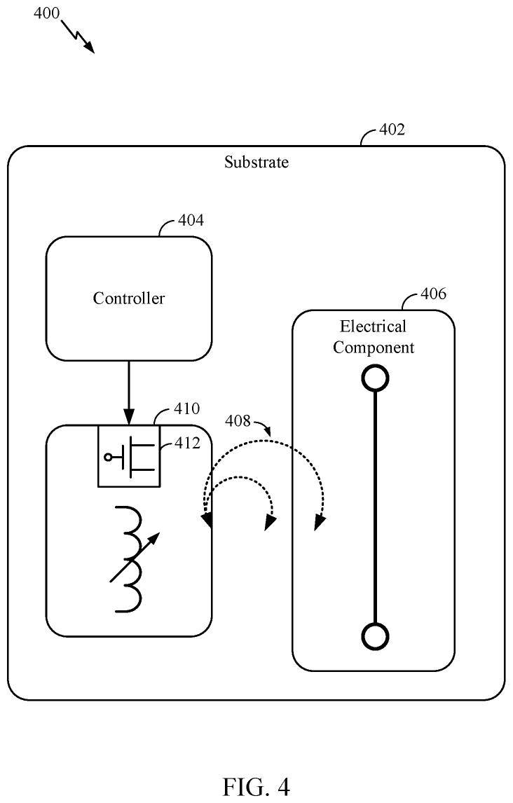

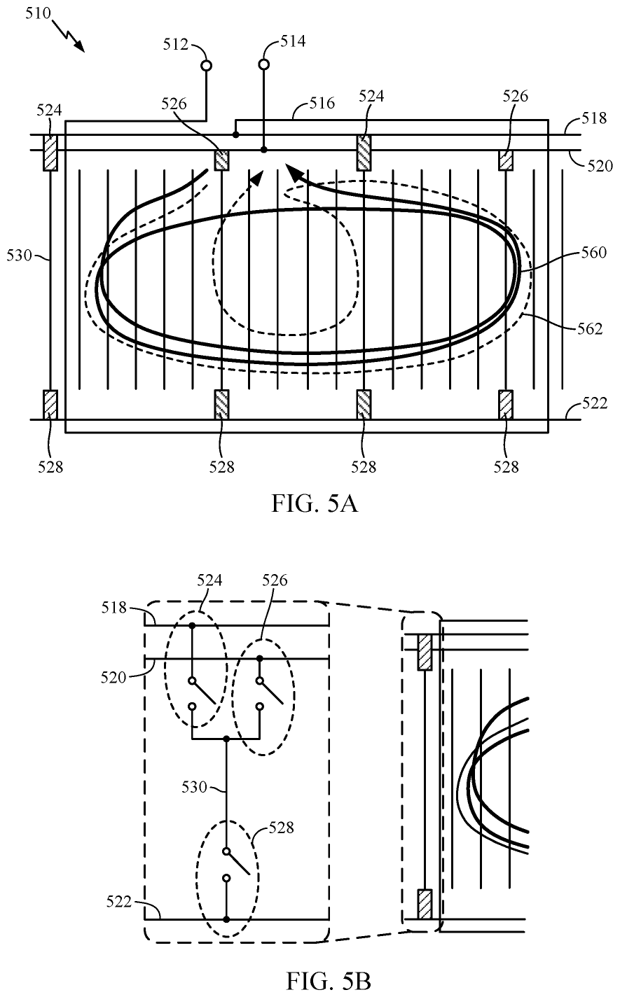

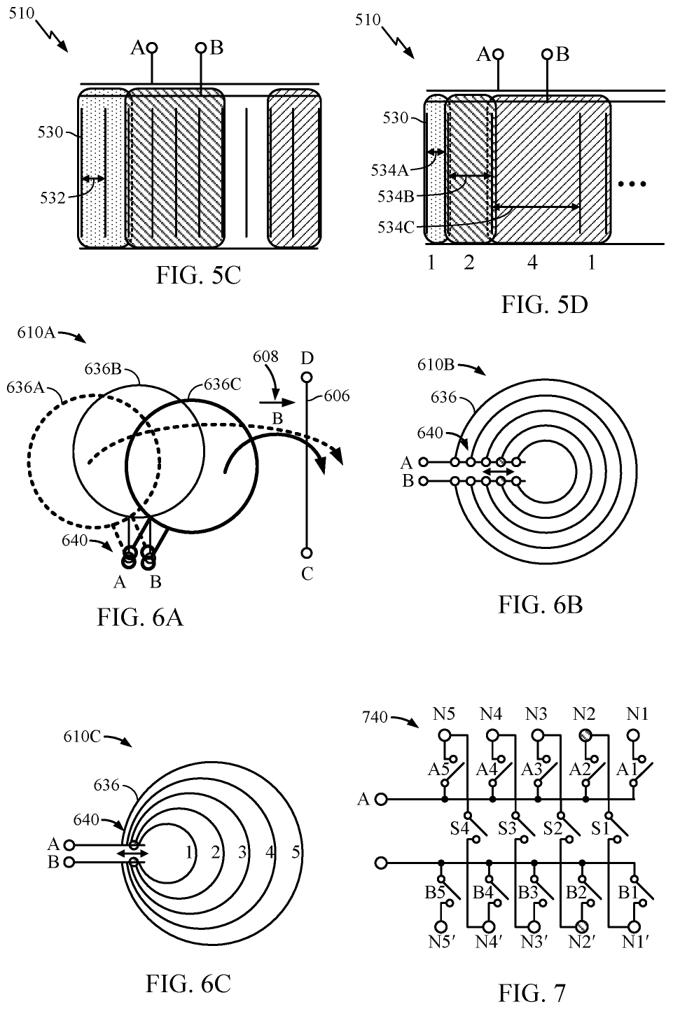

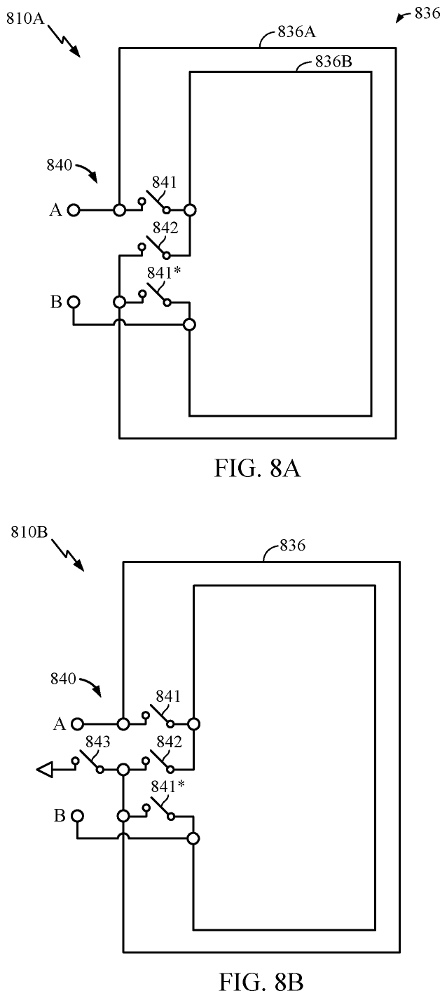

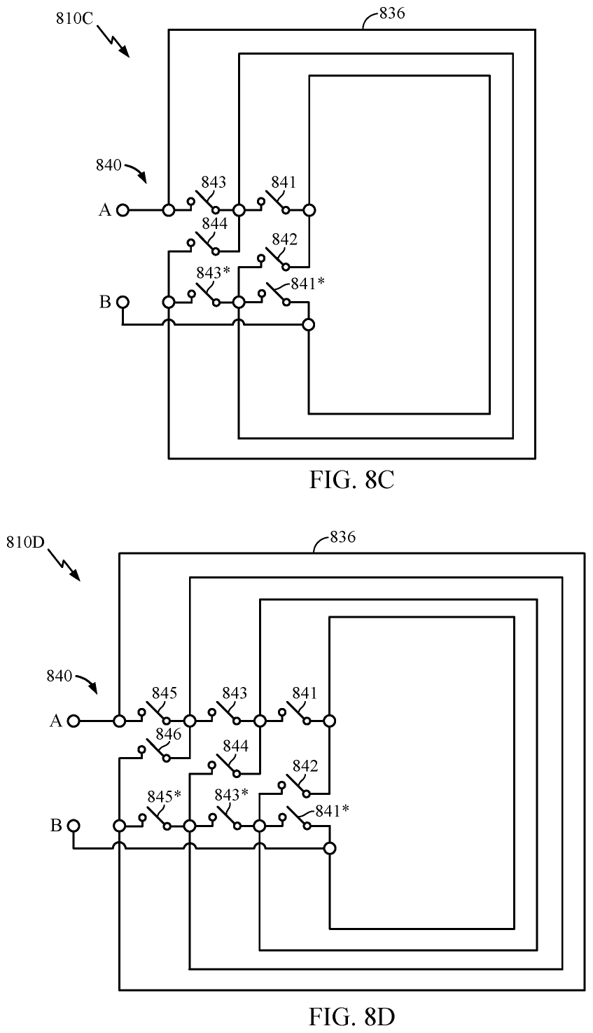

FIG. 4 illustrates a block diagram view of an example circuit configured to modify crosstalk between an inductive component and an adjacent electrical component, in accordance with certain aspects of the present disclosure. As shown, the circuit 400 includes a controller 404, an electrical component 406, and a variable inductive component 410. The variable inductive component 410 may produce magnetic field emissions, referred to herein as crosstalk 408. As the crosstalk 408 encounters the electrical component 406, an electric current may be induced in the electrical component 406, which may disturb an electrical signal intended to be conducted via the electrical component 406. The controller 404 may modify a characteristic of a component of the variable inductive component 410 in a way that modifies the crosstalk 408. This may enable the controller 404 to modify the crosstalk 408 such as to reduce the electrical disturbance by changing the phase or intensity of the magnetic field emissions produced by the variable inductive component 410 (described herein with respect to FIG. 5A) or adjusting the inductance or impedance of the variable inductive component 410 as further described herein. In certain aspects, the intensity of the magnetic field emissions encountered by the electrical component 406 may be varied by changing the position of an inductive coil of the variable inductive component 410 (e.g. as shown in FIG. 6A). In other aspects, a change of phase of the magnetic field emissions encountered by the electrical component 406 may occur when changing the current direction from clockwise to counterclockwise or vice versa of the current applied to the variable inductive component 410 (e.g., as shown in FIG. 5A). Modifying the intensity and the phase of the magnetic field emissions produced by the variable inductive component 410 may be used simultaneously. In certain aspects, the variable inductive component 410 may control switches to change the variable inductive component 410 functioning as an inductor to a transformer or vice versa (e.g., as shown in FIG. 8B).

The controller 404, electrical component 406, and variable inductive component 410 may be coupled to or arranged on a substrate 402, such as a package substrate, a laminate, an interposer, a printed circuit board (PCB) substrate, low temperature co-fired ceramic (LTCC) substrate, high temperature co-fired ceramic (HTCC) substrate, or any suitable multilayer structure. The substrate 402 may form a chip comprising the circuit 400. In certain aspects, the electrical component 406 and the variable inductive component 410 may be arranged on different substrates or chips. For example, the controller 404 may be on a different substrate or chip.

The controller 404 is configured to modify crosstalk 408 between the variable inductive component 410 and electrical component 406 by controlling switches 412 of the variable inductive component 410. The controller 404 may adjust an inductance, a phase, or an impedance of the variable inductive component 410 by controlling the switches 412. The controller 404 may be included in a processing system as a processor, a microcontroller, an application specific integrated circuit (ASIC), a field programmable gate array (FPGA) or other programmable logic device (PLD), discrete gate or transistor logic, a combination thereof. The controller 404 is coupled to control inputs of the switches 412, which enable or disable certain conductor paths of the variable inductive component 410, as further described herein, to vary the inductance or impedance of the variable inductive component 410 and/or vary the phase or intensity of the magnetic field emissions produced by the variable inductive component 410.

The electrical component 406 may be a conductor path, a bus bar, a passive element (e.g., a capacitor, resistor, inductor, antenna, transformer, diode, etc.), a digital element (e.g., a transistor, a register, a PLD, etc.), a power source (e.g., a voltage source or current source), or any analog or digital circuit. A bus bar may include any conductive path implemented in an electrical circuit, such as a conductive trace and/or via embedded in an integrated circuit. For example, the electrical component 406 may be any one of the components in the transceiver front end 300 of FIG. 3, and the variable inductive component 410 may also be an inductive electrical component in the transceiver front end 300, such as an inductor in the baseband filters 310, 326 or a winding of a transformer. The controller 404 may control the switches 412 of the variable inductive component 410 to modify the crosstalk between the variable inductive component 410 and electrical component 406, thereby reducing the electrical disturbance caused by the crosstalk 408.

In certain aspects, the example circuit 404 may be configured to reduce the crosstalk between electrical components. For example, the controller 404 may be configured to control the switches 412 of the variable inductive component 410 to adjust an inductance of the variable inductive component 410 to a selected inductance value. The controller 404 may also be further configured to control the switches 412 to alter a direction of current through at least one of the one or more conductive paths that form the coils of the variable inductive component 410 while maintaining the inductance at the selected inductance value.

In certain aspects, switches may be arranged between the conductors of the variable inductive component to enable or disable various conductor paths that form the windings of the inductive component. For example, FIG. 5A illustrates a schematic view of an example variable inductor, in accordance with certain aspects of the present disclosure. As shown, the variable inductor 510 includes an input terminal 512, an output terminal 514, a fixed coil 516, a first bus bar 518, a second bus bar 520, a third bus bar 522, and intermediate conductors 530. Switches 524, 526, 528 are also arranged between the intermediate conductors 530 and the bus bars 518, 520, 522. These components may be coupled to or arranged on a substrate material (e.g., substrate 402).

The intermediate conductors 530 and bus bars 518, 520, 522 are arranged, for example, in a ladder-like structure and make up various conductor paths for enabling or disabling one or more coils or coil turns. The input terminal 512 is electrically coupled to the first bus bar 518 via the fixed coil 516. The fixed coil 516 may be arranged above or below the intermediate conductors 530 and bus bars 518, 520, 522. Each intermediate conductor 530 is coupled to the bus bars 518, 520, 522 via switches 524, 526, 528. That is, in this example, each intermediate conductor 530 has a set of the switches 524, 526, 528 coupled to the bus bars 518, 520, 522. The switches 524, 526, 528 are coupled to the conductor paths (e.g., the intermediate conductors 530 and bus bars 518, 520, 522) to form different coil arrangements for variable inductor.

These switches enable the variable inductor to modify its coil size and current direction via the conductor paths formed by the intermediate conductors 530 and bus bars 518, 520, 522. For example, the controller may adjust an inductance or an impedance of the variable inductor 510 by varying a size of one or more of the coils formed by the conductor paths (e.g., the intermediate conductors 530 and bus bars 518, 520, 522) coupled to the switches 524, 526, 528 closed by the controller. The controller may also reverse a phase of the variable inductor by reversing a direction of current applied to the conductor paths via the switches 524, 526 coupled to the terminals 512, 514 of the variable inductor.

Two example coil configurations for the conductor paths are shown in FIG. 5A to form the inner coil from the intermediate conductors 530 and bus bars 518, 520, 522. In one example, the outer switches 524, 526, 528 may form an inner coil that provides the variable inductor 510 with two windings having the same current orientation as indicated by the current path 560. As another example, the inner switches 524, 526, 528 may form an inner coil which provides the variable inductor 510 with two windings having different current directions as indicated by the current path 562. This may enable the variable inductor 510 to cancel out a portion of the crosstalk encountered at the electrical circuit. As shown in these examples, the switches 524, 526, 528 enable the controller to change a current direction in one or more of the conductor paths of the variable inductor as indicated by the current paths 560, 562.

FIG. 5B illustrates a schematic view of a portion of the variable inductor 510 of FIG. 5A, in accordance with certain aspects of the present disclosure. As shown, the switches 524, 526 are arranged on separate branches of the intermediate conductor 530. The switch 524 is coupled between the first bus bar 518 and the intermediate conductor 530; the switch 526 is coupled between the second bus bar 520 and the intermediate conductor 530; and the switch 528 is coupled between the third bus bar 522 and the intermediate conductor 530. The portion of the variable inductor 510 shown in FIG. 5B may apply to any of the intermediate conductors 530 arranged between the bus bars 518, 520, 522 of the variable inductor 510.

In certain aspects, the conductor paths may include a plurality of conductor portions selectively coupled to various turn portions via one or more of the switches. As an example, each of the conductor portions may be selectively coupled to a first turn portion (e.g., fixed coil 516 coupled to the first bus bar 518) via a respective first switch (e.g., switch 524) of the one or more switches on a first side of the respective conductor portion. Each of the conductor portions may also be selectively coupled to a second turn portion (e.g., the second bus bar 520) via a respective second switch (e.g., switch 526) of the one or more switches on the first side of the respective conductor portion.

In certain aspects, the variable inductor may include multiple fixed coils arranged in various positions relative to the intermediate conductors 530 and bus bars 518, 520, 522. As examples, the fixed coils may be arranged above, below, partially above, partially below, and tilted (e.g., at 900 angle) in relation to the variable inductive components (e.g., the intermediate conductors 530, and bus bars 518, 520, 522). The variable inductor may also include multiple layers of intermediate conductors 530 and bus bars 518, 520, 522 to provide multiple conductor paths that form variable coils.

In certain aspects, the spacing between the intermediate conductors may vary or be the same to achieve, for example, a wide array of coil configurations to adjust the variable inductor. For example, FIGS. 5C and 5D illustrate schematic views of example conductor spacing of the variable inductor of FIG. 5A, in accordance with certain aspects of the present disclosure. As shown in FIG. 5C, the intermediate conductors 530 have the same spacing 532 between each other. This may enable the variable inductor to shift the coil laterally or vary the coil size to modify the crosstalk. As shown in FIG. 5D, the intermediate conductors 530 are spaced from each other based on different spacings 534A-C. In certain aspects, the intermediate conductors 530 may be spaced from each other based on a linear or non-linear spacing (e.g., an exponential or binary-weighted spacing). For instance, the intermediate conductors 530 of FIG. 5D may be spaced from each other based on a binary-weighted spacing. That is, the spacing 534B may be twice as long as the spacing 534A, and the spacing 534C may be twice as long as the spacing 534C. A binary-weighted spacing may enable the variable inductor to vary the coil size with fewer intermediate conductors and switches.

In certain aspects, the variable inductor may include one or more conductor paths forming a plurality of coils, and each coil may have a different spacing from the electrical component. This may enable the controller to modify the intensity of the crosstalk encountered at the electrical component based on the spacing of the electrical component to the coil of the variable inductor. The controller may enable one or more coils of the variable inductor via the switches based on a spacing of the selected coils from the electrical component to reduce crosstalk between the variable inductor and the electrical component. For example, FIG. 6A illustrates a schematic view of an example variable inductor that has a different spacing from the electrical component for each coil, in accordance with certain aspects of the present disclosure. As shown, the variable inductor 610A has coils 636A-C coupled to a switch network 640, which may enable or disable coils of the variable inductor 610A. Each of the coils 636A-C has a different spacing from the electrical component 606, which may provide a different intensity of crosstalk encountered at the electrical component. For example, when the coil 636A is enabled, the crosstalk 608 may be the weakest at the electrical component 606; whereas, the crosstalk 608 may be the strongest at the electrical component 606 when the coil 636C is enabled. The variable inductor 610A may be able to reduce the crosstalk 608 encountered at the electrical component 606 by switching from the coil 636C to the coil 636A. The variable inductor 610A may be able to increase the crosstalk 608 encountered at the electrical component 606 by switching from the coil 636A to the coil 636C. The switches of the switch network 640 may be coupled to the coils 636A-C to select at least one of the different spacings from the electrical component 606. In certain aspects, the coils of the variable inductor may have different spacings from the electrical component relative to a vertical, horizontal, or depth dimension.

In certain aspects, the coils of the variable inductor may be arranged concentrically or coaxially. For example, FIG. 6B illustrates a schematic view of an example variable inductor, in accordance with certain aspects of the present disclosure. As shown, the variable inductor 610B has coils 636 arranged concentrically from each other and coupled to a switch network 640. The switch network 640 may facilitate one or more coils 636 to be enabled.

In certain aspects, the coils of the variable inductor may be arranged to have a common axis on an edge of the coils. For example, FIG. 6C illustrates a schematic view of an example variable inductor, in accordance with certain aspects of the present disclosure. As shown, the variable inductor 610C has coils 636 arranged to be proximate to a common edge of the coils 636 and coupled to a switch network 640. The switch network 640 may facilitate one or more coils to be enabled. Aspects of the variable inductors of FIGS. 6A-C may also apply to coils having other suitable shapes than the rings depicted in FIGS. 6A-C. Aspects of the variable inductor of FIG. 5A with respect to changing the phase of the magnetic field emissions may also be employed with respect to FIGS. 6A-C. For example, the switch network 640 may be controlled to change the current direction conducted through any of the coils 636.

FIG. 7 illustrates a schematic view of an example switch network, in accordance with certain aspects of the present disclosure. As shown, the switch network has a plurality of input switches A1-A5, cross switches S1-S4, and output switches B1-B5. These switches facilitate the selection of one or more coils (e.g., coils 636) to modify the phase and/or intensity of the magnetic field emissions, or the inductance, impedance, spacing, or size of the variable inductor. In certain aspects, the switch network may be configured according to the characteristics of the variable inductor that are available for modification (such as the phase and/or intensity of the magnetic field emissions, or the inductance, impedance, spacing, or size of the variable inductor).

In certain aspects, the variable inductor may have two or more fixed-size coils coupled via a switch network. For example, FIGS. 8A-D illustrate schematic views of example variable inductors, in accordance with certain aspects of the present disclosure. As shown in FIG. 8A, the variable inductor 810A has two coils 836 or coil turns (e.g., a first outer coil turn 836A and a second inner coil turn 836B at least partially enclosed by outer coil turn) coupled via a switch network 840. The inductance between ports A (input terminal) and B (output terminal) may be modified by enabling or disabling the switches 841, 842, 841* of the switch network 840. Each of the switches 841, 842, 841* is coupled between the first outer coil turn 836A and the second inner coil turn 836B. One winding may be selected if only switch 841 or 841* is closed. A parallel circuit of two windings may be formed if switches 841 and 841* are closed. Two windings may be selected if switches 841, 841*, and 842 are closed.

As shown in FIG. 8B, the variable inductor 810B is similar to the variable inductor 810A, except that an additional switch 843 is coupled to a reference voltage (such as ground or other biasing voltage). This may enable the variable inductor 810B to selectively be shunted to ground or a reference voltage. FIG. 8C and FIG. 8D show similar variable inductors 810C and 810D with three and four windings respectively. Referring to FIG. 8C, the variable inductor 810C has switches 843, 844, and 843* coupled to the third coil 836. Referring to FIG. 8D, the variable inductor 810D has switches 845, 846, and 845* coupled to the fourth coil 836. In certain aspects, the switch network 840 of the variable inductor 810A (or 810B-D) may be controlled to modify the phase or intensity of the magnetic field emissions or the inductance, impedance, spacing, or size of the variable inductor 810A (or 810B-D) to modify the crosstalk between an electrical component and the variable inductor.

As an example, the outer coil 836 of the variable inductor 810D may be selected by closing switches 845*, 843*, and 841*. As another example, the inner and outer coils 836 of the variable inductor 810D may be selected by closing switches 846, 843, and 841. In a third example, the fourth, third, and first coils 836 of the variable inductor 810D may be selected by closing switches 845*, 843, and 841, which results in the direction of current in the third coil flowing in the opposite direction relative to the current in the fourth and first (outer and inner) coils. In the third example, enabling the opposite current direction in the third coil may reduce the magnetic field emissions of the variable inductor 810D.

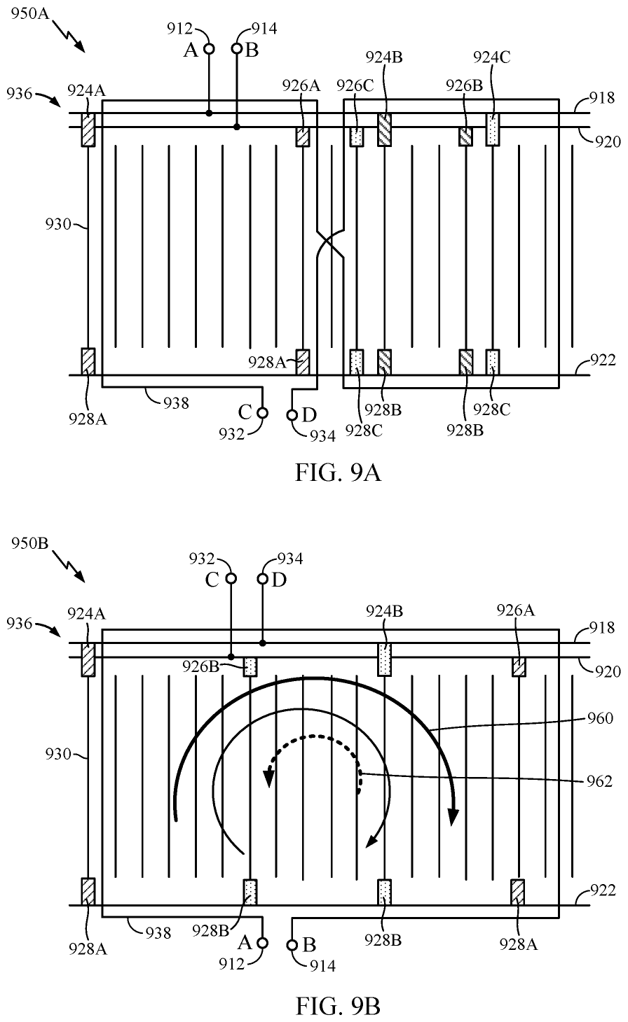

In certain aspects, the techniques described above to modify crosstalk from a variable inductor may be applied to a transformer having a variable winding path. That is, a transformer may include as one of its windings a variable inductor as described herein. For example, FIGS. 9A and 9B illustrate schematic views of example variable transformers, in accordance with certain aspects of the present disclosure. As shown in FIG. 9A, the variable transformer 950A includes a variable winding path 936 and a fixed winding path 938. The variable winding path 936 is configured as the primary winding path and constructed similar to the variable inductor of FIG. 5A. The fixed winding path 938 may be coupled to output ports 932, 934 and arranged above or below the variable winding path 936. The fixed winding path 938 is arranged in a figure-eight shape. This enables a coil to be formed from the variable winding path 936 that conducts current in the same direction or a different direction than the fixed winding path 938.

For example, the switches 924A, 926A, 928A may be selected to form a coil that has a high coupling with a loop of the fixed winding path 938 and produce a phase shift of 0° at the output ports 932, 934. The switches 924B, 926B, 928B may be selected to form a coil that is smaller than a loop of the figure-eight, yielding a reduced coupling. This coil may produce a 180° phase shift at the output ports 932, 934. As another example, the switches 924C, 926C, 928C may be selected to form a coil that has a medium coupling a loop of the fixed winding path 938 and produces a phase shift of 0°. In certain aspects, the variable winding path 936 may have parallel coils enabled. For example, the switches 924A, 926A, 928A, 924C, 926C, 928C may be selected to form two parallel coils coupled to the ports 912, 914.

In certain aspects, the secondary winding path may be the variable winding path similar to the variable inductor of FIG. 5A. For example, as shown in FIG. 9B, the variable transformer 950B includes the variable winding path 936 and the fixed winding path 938, which may form a portion of a loop, a full loop (as shown), or more than one loop. The variable winding path 936 is configured as the secondary winding path having output ports 932, 934. Two example secondary winding paths are depicted in FIG. 9B. As an example, the switches 924A, 926A, 928A are selected to form a coil that has a high coupling with the fixed winding path 938 and in phase with the secondary winding path as indicated by the current direction 960. As another example, the switches 924B, 926B, 928B are selected to form a coil that has a reduced coupling with the fixed winding path 938 and a phase shift of 180° with the secondary winding path as indicated by the current direction 962.

In certain aspects, the variable transformer may include multiple fixed coils arranged on the primary winding path and/or secondary winding path. The variable transformer may also include multiple layers of variable winding paths 936 arranged on the primary winding path and/or the secondary winding path.

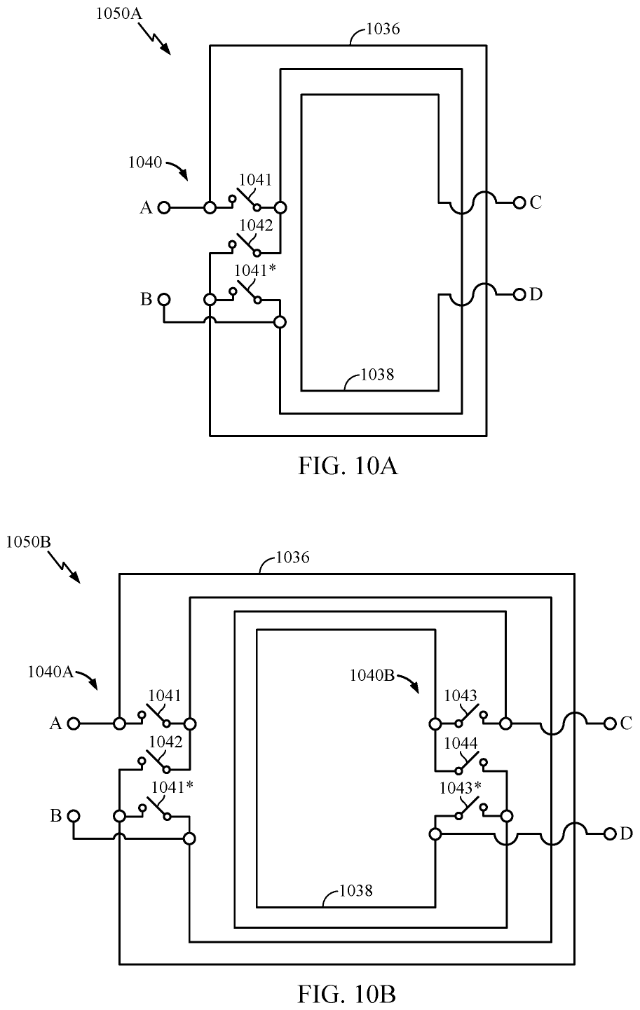

As another example, FIGS. 10A and 10B illustrate schematic views of example variable transformers, in accordance with certain aspects of the present disclosure. As shown in FIG. 10A, the variable transformer 1050A includes a primary winding having two variable coils 1036 and a secondary winding having a fixed coil 1038. The variable coils 1036 are coupled to a switch network 1040 having switches 1041, 1042, and 1041* and operating similar to the variable inductor 810A of FIG. 8A.

As shown in FIG. 10B, the variable transformer 1050B includes a primary winding path having primary variable coils 1036 and a secondary winding path having secondary variable coils 1038. That is, the variable transformer 1050B is similar to the variable transformer 1050A, except that the variable transformer 1050B has multiple variable coils arranged on both windings. The primary variable coils 1036 are coupled to the switch network 1040A having switches 1041, 1042, and 1041*, and the secondary variable coils 1038 are coupled to the switch network 1040B having switches 1043, 1044, and 1043*. Both of these switch networks operate similar to the variable inductor 810A of FIG. 8A. In certain aspects, the variable coils may be arranged on three-phase transformers.

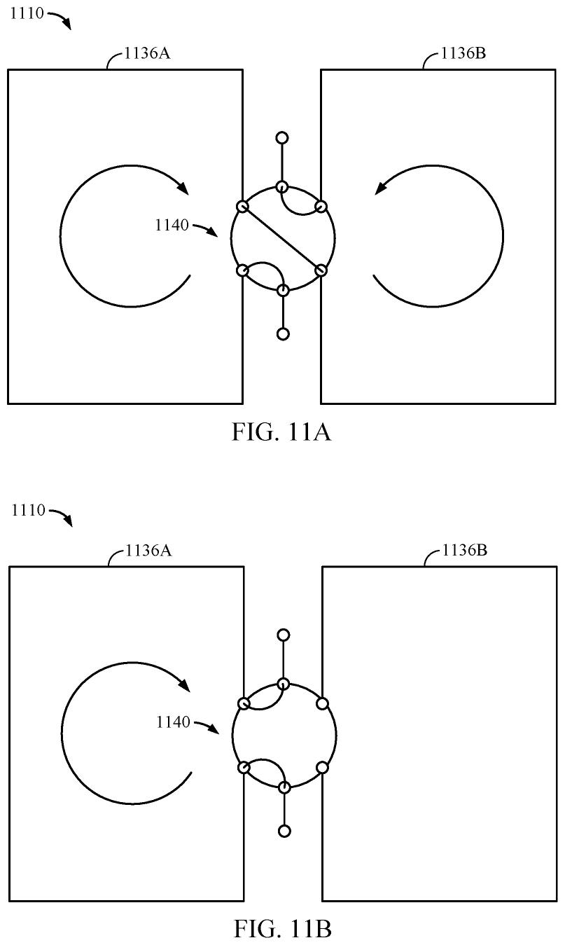

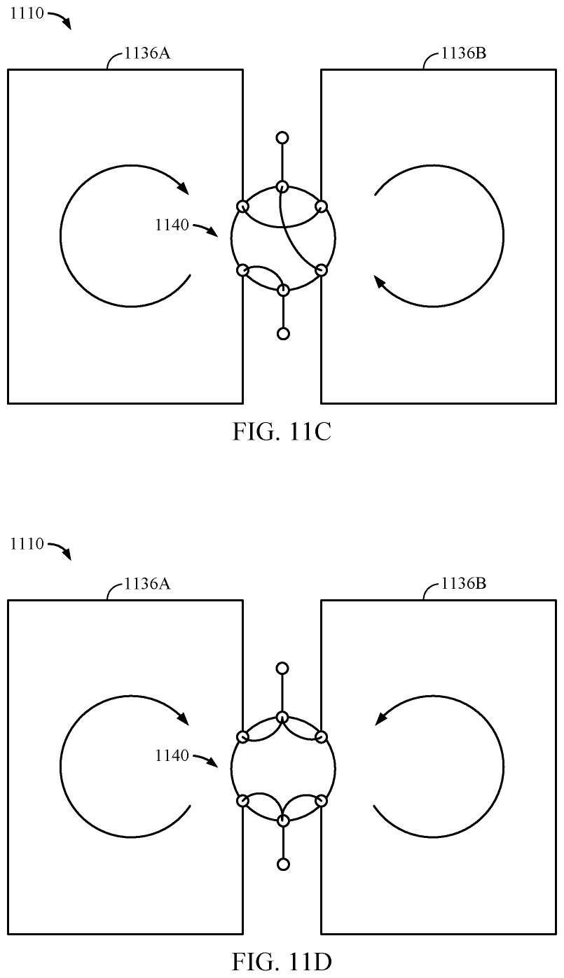

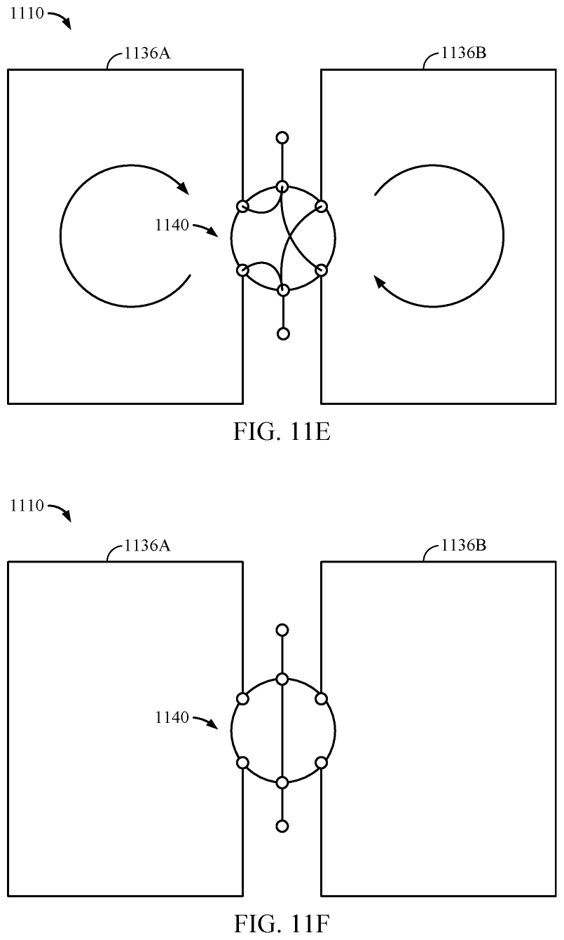

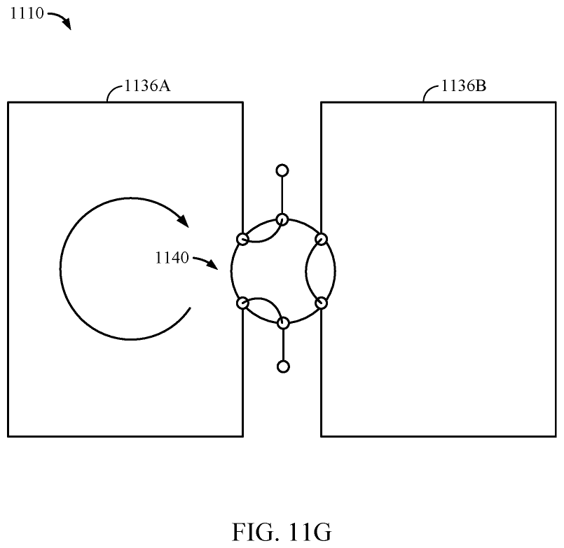

FIGS. 11A-G illustrate schematic views of various switch configurations of a variable inductor, in accordance with certain aspects of the present disclosure. As shown in FIG. 11A, the variable inductor 1110 includes a first coil 1136A, a second coil 1136B, and a switch network 1140. The switch network 1140 is configured to conduct current through the second coil 1136B in the opposite direction as the current in the first coil 1136A. Also, the second coil 1136B is coupled in series with the first coil 1136A via the switch network. This may enable the coils 1136A, 1136B to cancel out a portion of the crosstalk emitted from the variable inductor 1110, while increasing the inductance of the variable inductor 1110.

As shown in FIG. 11B, the switch network 1140 is configured to conduct current only through the first coil 1136A, while the second coil 1136B is open via the switch network. This may enable the variable inductor 1110 to reduce its inductance and crosstalk emissions.

As shown in FIG. 11C, the switch network 1140 is configured to conduct current through the second coil 1136B in the same direction as the current in the first coil 1136A. The second coil 1136B is also coupled in series with the first coil 1136A via the switch network 1140. This may enable the variable inductor 1110 to increase its inductance and crosstalk emissions.

As shown in FIG. 11D, the switch network 1140 is configured to conduct current through the second coil 1136B in the opposite direction as the current in the first coil 1136A. The second coil 1136B is coupled in parallel with the first coil 1136A via the switch network. This may enable the variable inductor 1110 to reduce its inductance and crosstalk emissions.

As shown in FIG. 11E, the switch network 1140 is configured to conduct current through the second coil 1136B in the same direction as the current in the first coil 1136A. The second coil 1136B is also coupled in parallel with the first coil 1136A via the switch network 1140. This may enable the variable inductor 1110 to reduce its inductance, but increase its crosstalk emissions.

As shown in FIG. 11F, the switch network 1140 is configured to short the coils 1136A, 1136B. This enables the variable inductor 1110 to provide effectively no inductance and crosstalk emissions.

As shown in FIG. 11G, the switch network 1140 is configured to conduct current only through the first coil 1136A, while the second coil 1136B is closed via the switch network 1140. This may enable the second coil 1136B to serve as a shield or reflector of the crosstalk emissions depending on the orientation of the electrical component and enable the variable inductor 1110 to reduce its inductance.

FIG. 12 is a flow diagram illustrating example operations 1200 that may be performed, for example, by a circuit (e.g., circuit 400) configured to modify crosstalk between electrical components (such as the electrical component 406 and the variable inductive component 410), in accordance with certain aspects of the present disclosure.

Operations 1200 may begin, at 1202, where a signal source (e.g., DAC 308, mixer 324, or antenna 303) may apply a signal to a variable inductive component comprising switches and one or more conductor paths. For example, the variable inductive component may be included in one of the baseband filters 310, 326 of the transceiver front end 300. The signal applied to the variable inductive component may be from any of the components coupled to the input of one of the baseband filters 310, 326.

At 1204, a controller (e.g., controller 404) may control the switches of the variable inductive component to modify crosstalk between the variable inductive component and the electrical component. As described herein, the controller 404 may adjust an inductance or an impedance of the variable inductive component or adjust a phase of the magnetic field emissions by controlling the switches. The controller may adjust an inductance or an impedance of the variable inductive component by varying a size of one or more of the coils formed by the conductor paths coupled to the switches closed by the controller. The controller may also reverse a phase of the magnetic field emissions component by reversing a direction of current applied to the conductor paths via the switches coupled to the input terminals of the variable inductive component.

In certain aspects, controlling the switches may include controlling the switches to change a current direction of the variable inductive component. Controlling the switches may also include enabling one or more coils of the conductor paths via the switches according to a spacing of the one or more coils from the electrical component. As another example, controlling the switches may include adjusting at least one of an inductance or an impedance of the variable inductive component by selecting different coils formed from the conductive paths via the switches coupled to input terminals of the variable inductive component. In other aspects, controlling the switches may include adjusting a phase of magnetic field emissions produced by the variable inductive component by changing a direction of current applied to the conductor path via the switches coupled to input terminals of the variable inductive component.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

The various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the PHY layer. In the case of an UE 120 (see FIG. 1), a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further. The processor may be implemented with one or more general-purpose and/or special-purpose processors. Examples include microprocessors, microcontrollers, DSP processors, and other circuitry that can execute software. Those skilled in the art will recognize how best to implement the described functionality for the processing system depending on the particular application and the overall design constraints imposed on the overall system.

If implemented in software, the functions may be stored or transmitted over as one or more instructions or code on a computer readable medium. Software shall be construed broadly to mean instructions, data, or any combination thereof, whether referred to as software, firmware, middleware, microcode, hardware description language, or otherwise. Computer-readable media include both computer storage media and communication media including any medium that facilitates transfer of a computer program from one place to another. The processor may be responsible for managing the bus and general processing, including the execution of software modules stored on the machine-readable storage media. A computer-readable storage medium may be coupled to a processor such that the processor can read information from, and write information to, the storage medium. In the alternative, the storage medium may be integral to the processor. By way of example, the machine-readable media may include a transmission line, a carrier wave modulated by data, and/or a computer readable storage medium with instructions stored thereon separate from the wireless node, all of which may be accessed by the processor through the bus interface. Alternatively, or in addition, the machine-readable media, or any portion thereof, may be integrated into the processor, such as the case may be with cache and/or general register files. Examples of machine-readable storage media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product.

A software module may comprise a single instruction, or many instructions, and may be distributed over several different code segments, among different programs, and across multiple storage media. The computer-readable media may comprise a number of software modules. The software modules include instructions that, when executed by an apparatus such as a processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module.

Also, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For example, instructions for performing the operations are described herein and illustrated in FIG. 12.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the methods and apparatus described above without departing from the scope of the claims. cm What is claimed is:

1. A circuit for reducing crosstalk between components, the circuit comprising:
a variable inductive component comprising one or more switches and a plurality of conductor paths; and
a controller configured to control the one or more switches of the variable inductive component to adjust an inductance of the variable inductive component to a selected inductance value, the controller further configured to control the one or more switches to alter a direction of current through at least one of the plurality of conductor paths, wherein the controller is configured to control the one or more switches to alter the direction of current while the inductance is maintained at the selected inductance value.

2. (canceled)

3. The circuit of claim 1, wherein the plurality of conductor paths comprises:
a first conductor forming at least one coil turn and coupled to an input terminal of the variable inductive component;
a second conductor coupled to the first conductor;
a third conductor coupled to an output terminal of the variable inductive component;
a fourth conductor; and
a plurality of intermediate conductors, wherein each of the plurality of the intermediate conductors is:
selectively coupled to the second conductor via a respective first switch of the one or more switches;
selectively coupled to the third conductor via a respective second switch of the one or more switches; and
selectively coupled to the fourth conductor via a respective third switch of the one or more switches.

4. The circuit of claim 1, wherein the plurality of conductor paths comprise a first bus bar, a second bus bar, a third bus bar, and intermediate conductors arranged between the first, second, and third bus bars, wherein the one or more switches are coupled between the first bus bar and the intermediate conductors, between the second bus bar and the intermediate conductors, and between the third bus bar and the intermediate conductors.

5. The circuit of claim 1, wherein the plurality of conductor paths comprises a plurality of conductor portions, wherein each of the plurality of conductor portions is:
selectively coupled to a first turn portion via a respective first switch of the one or more switches on a first side of the respective conductor portion; and
selectively coupled to a second turn portion via a respective second switch of the one or more switches on the first side of the respective conductor portion.

6. The circuit of claim 1, wherein the plurality of conductor paths comprises:
a first outer coil turn coupled to an input terminal; and
a second inner coil turn at least partially enclosed by the first outer coil turn and coupled to an output terminal, wherein the one or more switches comprises:
a first switch coupled between the first outer coil turn and the second inner coil turn;
a second switch coupled between the first outer coil turn and the second inner coil turn; and
a third switch coupled between the first outer coil turn and the second inner coil turn.

7. A circuit, comprising:
an electrical component;
a variable inductive component comprising switches and one or more conductor paths; and
a controller configured to control the switches of the variable inductive component to adjust a phase of magnetic field emissions, which are produced by the variable inductive component, to modify crosstalk between the variable inductive component and the electrical component.

8. The circuit of claim 7, wherein:
the switches are coupled to the conductor paths to change a direction of current in one or more of the conductor paths of the variable inductive component; and
the controller is configured to control the switches to change the direction of current in the one or more of the conductor paths.

9. The circuit of claim 7, wherein:
the conductor paths form a plurality of coils;
each of the plurality of coils has a different spacing from the electrical component;
the switches are coupled to the plurality of coils to select at least one of the different spacings from the electrical component; and
the controller is configured to enable at least one of the plurality of coils via the switches based on a spacing of the at least one of the plurality of coils from the electrical component to reduce crosstalk between the variable inductive component and the electrical component.

10. The circuit of claim 7, wherein the variable inductive component comprises a transformer.

11. The circuit of claim 7, wherein the switches are coupled to the conductor paths to form different coil arrangements for the variable inductive component.

12. The circuit of claim 7, wherein the controller is configured to adjust at least one of an inductance or an impedance of the variable inductive component by controlling the switches.

13. (canceled)

14. The circuit of claim 7, wherein the controller is configured to adjust at least one of an inductance or an impedance of the variable inductive component by varying a size of one or more coils formed by the conductor paths coupled to switches closed by the controller.

15. The circuit of claim 7, wherein the controller is configured to reverse the phase of magnetic field emissions from the variable inductive component by reversing a direction of current applied to the conductor paths via the switches coupled to input terminals of the variable inductive component.

16. The circuit of claim 7, wherein the electrical component comprises at least one of a passive element, a bus bar, or another circuit.

17. The circuit of claim 7, wherein the conductor paths comprise one or more fixed-size coils comprising at least one coil in a figure-eight shape.

18. The circuit of claim 7, wherein the conductor paths comprise a first bus bar, a second bus bar, a third bus bar, and intermediate conductors arranged between the first, second, and third bus bars.

19. The circuit of claim 18, wherein the switches are coupled between the first bus bar and the intermediate conductors, between the second bus bar and the intermediate conductors, and between the third bus bar and the intermediate conductors.

20. A chip, comprising:
an electrical component arranged on a substrate material;
a variable inductive component comprising switches and one or more conductor paths arranged on the substrate material; and
a controller arranged on the substrate material and configured to control the switches of the variable inductive component to adjust a phase of magnetic field emissions, which are produced by the variable inductive component, to modify crosstalk between the variable inductive component and the electrical component.

21. The chip of claim 20, wherein
the switches are coupled to the conductor paths to change a direction of current in one or more of the conductor paths of the variable inductive component; and
the controller is configured to control the switches to change the direction of current in the one or more of the conductor paths.

22. The chip of claim 20, wherein:
the conductor paths form a plurality of coils;
each of the plurality of coils has a different spacing from the electrical component;
the switches are coupled to the plurality of coils to select at least one of the different spacings from the electrical component; and
the controller is configured to enable at least one of the plurality of coils via the switches based on a spacing of the at least one of the plurality of coils from the electrical component to reduce crosstalk between the variable inductive component and the electrical component.

23. The chip of claim 20, wherein:
the switches are coupled to the conductor paths to form different coil arrangements for the variable inductive component; and
the controller is configured to adjust at least one of an inductance or an impedance of the variable inductive component by controlling the switches.

24. (canceled)

25. The chip of claim 20, wherein:
the conductor paths comprise a first bus bar, a second bus bar, a third bus bar, and intermediate conductors arranged between the first, second, and third bus bars; and
the switches are coupled between the first bus bar and the intermediate conductors, between the second bus bar and the intermediate conductors, and between the third bus bar and the intermediate conductors.

26. A method of modifying crosstalk between electrical components, comprising:
applying a signal to a variable inductive component comprising switches and one or more conductor paths; and
controlling the switches of the variable inductive component to modify crosstalk between the variable inductive component and an electrical component, wherein controlling the switches comprises adjusting a phase of magnetic field emissions produced by the variable inductive component by changing a direction of current applied to the conductor path via the switches coupled to input terminals of the variable inductive component.

27. (canceled)

28. The method of claim 26, wherein controlling the switches comprises enabling one or more coils of the conductor paths via the switches according to a spacing of the one or more coils from the electrical component.

29. The method of claim 26, wherein controlling the switches comprises adjusting at least one of an inductance or an impedance of the variable inductive component by selecting different coils formed from the conductor paths via the switches coupled to input terminals of the variable inductive component.

30. (canceled)

31. (canceled)
